(19) United States
(12) Patent Application Publication
(10) Pub. No.: US 2022/0107399 A1
(43) Pub. Date: Apr. 7, 2022

(54) POSITION DETECTING DEVICE

(71) Applicant: TOYODA GOSEI CO., LTD., Kiyosu-shi (JP)

(72) Inventors: Ryusuke HORIBE, Kiyosu-shi (JP); Hiroshi YASUDA, Hirakata-shi (JP)

(21) Appl. No.: 17/486,217

(22) Filed: Sep. 27, 2021

(30) Foreign Application Priority Data
Oct. 1, 2020 (JP) 2020-167242

(51) Int. Cl. G01S 7/4861; G01S 17/06

(52) U.S. Cl. CPC G01S 7/4861; H03M 1/129; G01S 17/06

(57) ABSTRACT

A position detecting device includes light-emitting units, a light-receiving unit, an AD conversion unit, a position detecting unit, and an offset unit. The light-emitting units emit optical signals that are intensity-modulated using modulated signal streams of different phases. The light-receiving unit receives light reflected on an object and converts the reflected light into an analog signal. The position detecting unit detects a position of the object based on a digital signal converted by the AD conversion unit. The offset unit offsets a direct-current voltage level of the analog signal output from the light-receiving unit by an offset level, and outputs the analog signal to the AD conversion unit. The offset unit adjusts the offset level so as to cause an average of the analog signal input to the AD conversion unit to approach a median of an input voltage range of the AD conversion unit.

### BACKGROUND

### 1. Field

The present disclosure relates to a position detecting device that detects the position of an object.

### 2. Description of Related Art

Some position detecting devices, which detect the position of an object, are of an optical type (for example, Japanese Laid-Open Patent Publication No. 2011-215099).

A typical position detecting device of an optical type has the following structure. The position detecting device includes light-emitting units, a light-receiving unit, and a position detecting unit (processing circuit). The light-emitting units each emit an optical signal to an object. The light-receiving unit receives light reflected by the object and converts the received light into an electric signal. The position detecting unit (processing circuit) detects the position of the object based on the electric signal. The device is configured such that the processing circuit receives the electric signal via a low-frequency cutoff unit, which attenuates frequency components lower than a cutoff frequency.

When performing position detection, the position detecting device lights the light-emitting units sequentially and detects reflected light using the light-receiving unit. The received reflected light is input to the processing circuit. Then, the position of the object is calculated (detected) based on the quantity of the detected reflected light, specifically, the electric signal input to the processing circuit.

The low-frequency cutoff unit includes a high-pass filter circuit, which has a resistor and a capacitor. The resistor is biased by a specific voltage. Thus, the output signal changes in the following manner when the low-frequency cutoff unit receives a pulse stream that is detected by the light-receiving unit. That is, the electric signal amplitude (specifically, its peak value and average), which is output from the low-frequency cutoff unit, changes from a specific bias voltage and temporarily reaches an amplitude that corresponds to the amplitude of the pulse stream, at the beginning of input of the pulse stream to the low-frequency cutoff unit. Thereafter, the amplitude gradually decreases in accordance with a time constant, which is defined by a resistance value R of the resistor and a capacitance C of the capacitor, so that the average of the pulse stream gradually approaches the specific bias voltage. If the signal duty cycle of the pulse stream is 50%, the signal amplitude between the maximum peak and the minimum peak within the entire time domain is 1.5 times greater than the input amplitude of the low-frequency cutoff unit. The processing circuit is required to operate with a high degree of accuracy. In order to suppress offset and drift, which are analog phenomena, the processing circuit preferably includes an AD conversion unit in the initial stage, so that an input analog signal is converted into a digital signal before being processed in a digital circuit. In order to perform position detection normally, a signal must be input to the AD conversion unit so as not to exceed an input voltage range of the processing circuit. However, when passing through the low-frequency cutoff unit, the signal amplitude is increased. Accordingly, the signal amplitude must be attenuated before being input to the processing circuit.

There has been an objective contrary to the above. That is, in order to perform accurate position detection, the signal-to-noise ratio (SNR) of the electric signal input to the processing circuit needs to be maximized. Accordingly, in order to reduce the influence of the quantization noise of the AD conversion unit, the electric signal amplitude input to the AD conversion unit needs to be maximized within the input voltage range.

The signal value of an electric signal output from the light-receiving unit varies from moment to moment depending on the quantity of reflected light that is incident on the light-receiving unit. Thus, if an analog signal output from the light-receiving unit is simply input to the AD conversion unit, a large quantity of reflected light causes the maximum value of the analog signal input to the AD conversion unit to exceed the input voltage range. The analog signal thus cannot be converted properly, and position detection may not be performed normally.

To eliminate the above-described disadvantages, it is only necessary to reduce the input amplitude of the AD conversion unit. In this case, however, a small quantity of reflected light reduces the value of the analog signal input to the AD conversion unit in relation to the input voltage range of the AD conversion unit. This reduces the SNR of the AD conversion unit and thus may reduce the accuracy of the position detection by the position detecting device.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a position detecting device is provided that includes light-emitting units, a light-receiving unit, an AD conversion unit, a position detecting unit, and an offset unit. The light-emitting units emit optical signals that are intensity-modulated using modulated signal streams of different phases. The light-receiving unit receives reflected light and converts the reflected light into an analog signal. The reflected light is the optical signal reflected by an object. The AD conversion unit converts the analog signal into a digital signal. The position detecting unit detects a position of the object based on the digital signal converted by the AD conversion unit. The offset unit is arranged between the light-receiving unit and the AD conversion unit. The offset unit offsets a direct-current voltage level of the analog signal output from the light-receiving unit by an offset level, and outputs the analog signal to the AD conversion unit. The offset unit adjusts the offset level so as to cause an average of the analog signal input to the AD conversion unit during a modulation period, in which intensity-modulation is performed using the modulated signal streams, to approach a median of an input voltage range of the AD conversion unit.

Other features and aspects will be apparent from the following detailed description, the drawings, and the claims.

### BRIEF DESCRIPTION OF THE DRAWINGS

FIG. 1 is a schematic diagram showing a distance detection mode of a position detecting device according to one embodiment.

FIG. 2 is an explanatory diagram illustrating manners in which detection is performed in the distance detection mode.

FIG. 3 is a schematic diagram showing a tilt angle detection mode of the position detecting device.

FIG. 4 is an explanatory diagram illustrating manners in which detection is performed in the tilt angle detection mode.

FIG. 5 is a schematic diagram showing a detection circuit of the position detecting device.

FIG. 6 is a timing diagram showing various signal waveforms in the detection circuit.

FIG. 7 is a simplified diagram of a circuit structure of a synchronous detection unit.

FIG. 8 is a timing diagram showing signal waveforms in a position detecting device according to a comparative example.

FIG. 9 is a timing diagram showing an example of an AD conversion signal.

FIG. 10 is a flowchart showing an execution procedure of an operation control process of an offset unit.

FIG. 11 is a timing diagram showing signal waveforms in the position detecting device according to the embodiment of FIG. 1.

FIG. 12 is a timing diagram in which section (a) shows an IV conversion signal, and section (b) shows an offset signal.

FIG. 13 is a flowchart showing an execution procedure of a variable gain amplifying unit.

FIG. 14 is a timing diagram showing signal waveforms according to a modification.

FIG. 15 is a timing diagram showing signal waveforms according to the modification.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

This description provides a comprehensive understanding of the methods, apparatuses, and/or systems described. Modifications and equivalents of the methods, apparatuses, and/or systems described are apparent to one of ordinary skill in the art. Sequences of operations are exemplary, and may be changed as apparent to one of ordinary skill in the art, with the exception of operations necessarily occurring in a certain order. Descriptions of functions and constructions that are well known to one of ordinary skill in the art may be omitted.

Exemplary embodiments may have different forms, and are not limited to the examples described. However, the examples described are thorough and complete, and convey the full scope of the disclosure to one of ordinary skill in the art.

A position detecting device according to one embodiment will now be described.

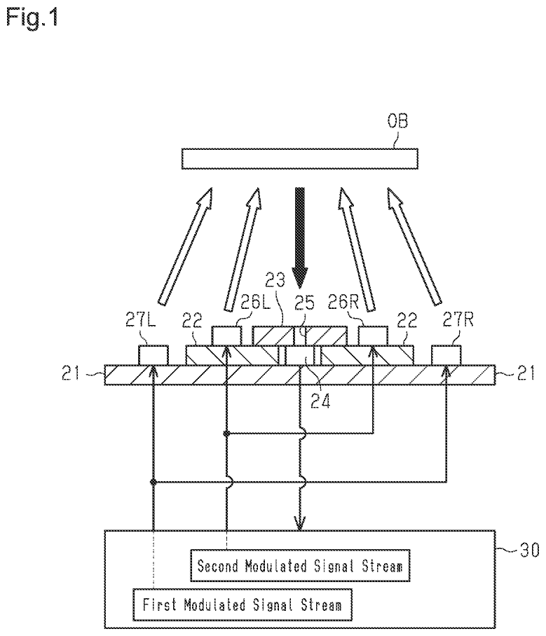

As shown in FIG. 1, the position detecting device of the present embodiment has a three-layer structure including a lower layer base 21, an intermediate layer base 22, and an upper layer base 23.

A light-receiving element 24 (a photodiode in the present embodiment) is provided on the lower layer base 21. The light-receiving element 24 detects the quantity of incident light. The light-receiving element 24 is located at the center of the lower layer base 21 on the side facing the intermediate layer base 22 (upper side as viewed in FIG. 1). The light-receiving element 24 is arranged in a gap between the lower layer base 21 and the upper layer base 23. The upper layer base 23 includes a through-hole (pinhole 25), which extends through the upper layer base 23 in a direction in which the bases are stacked (vertical direction as viewed in FIG. 1). The pinhole 25 is formed in a part that faces the light-receiving section of the light-receiving element 24. The position detecting device of the present embodiment has a structure in which external light is incident on the light receiving section of the light-receiving element 24 through the pinhole 25. In the present embodiment, the light-receiving element 24 corresponds to a light-receiving unit.

The position detecting device of the present embodiment includes four light-emitting elements 26L, 26R, 27L, 27R, which each emit an optical signal for position detection. In the present embodiment, the light-emitting elements 26L, 26R, 27L, 27R each include a light-emitting diode.

Two of the four light-emitting elements (inner light-emitting elements 26L, 26R) are provided on a surface of the intermediate layer base 22 that faces the upper layer base 23 (upper surface as viewed in FIG. 1). The upper layer base 23 is not provided in sections where the inner light-emitting elements 26L, 26R are provided. The inner light-emitting elements 26L, 26R are arranged so as to emit optical signals in a direction away from the intermediate layer base 22 (upward as viewed in FIG. 1).

The remaining two of the four light-emitting elements (outer light-emitting elements 27L, 27R) are provided on a surface of the lower layer base 21 that faces the intermediate layer base 22 (upper surface as viewed in FIG. 1). Neither the intermediate layer base 22 nor the upper layer base 23 is provided in sections where the outer light-emitting elements 27L, 27R are provided. The outer light-emitting elements 27L, 27R are arranged so as to emit optical signals in a direction away from the lower layer base 21 (upward as viewed in FIG. 1).

In the position detecting device of the present embodiment, the four light-emitting elements 26L, 26R, 27L, 27R and the light-receiving element 24 are arranged on a single straight line in a plan view (as viewed from the top in FIG. 1). Specifically, the inner light-emitting elements 26L, 26R are arranged on opposite sides of the light-receiving element 24, so as to be equally distanced from the light-receiving element 24. Also, the outer light-emitting elements 27L, 27R are arranged on opposite sides of the light-receiving element 24 and the inner light-emitting elements 26L, 26R, so as to be equally distanced from the light-receiving element 24. The outer light-emitting elements 27L, 27R are arranged on the outer sides of the inner light-emitting elements 26L, 26R in the direction which the four light-emitting elements 26L, 26R, 27L, 27R are arranged. In the position detecting device of the present embodiment, the distances between the inner light-emitting elements 26L, 26R and the light-receiving element 24 are shorter than the distances between the outer light-emitting elements 27L, 27R and the light-receiving element 24. In the present embodiment, the light-emitting elements 26L, 26R, 27L, 27R each correspond to a light-emitting unit.

The position detecting device of the present embodiment performs position detection of an object through synchronous detection.

The position detecting device of the present embodiment outputs, as drive signals for causing the light-emitting elements to blink, two types of modulated signal streams (a first modulated signal stream and a second modulated signal stream) of which the phases are displaced from each other by 90 degrees (specifically, a quarter of the wavelength). The first modulated signal stream and the second modulated signal stream are rectangular waves of a specific modulation frequency (40 kHz in the present embodiment).

When the position detecting device of the present embodiment performs position detection, a first light-emitting element LED1 is first driven by the first modulated signal stream to emit light. Then, after a phase delay of 90 degrees, a second light-emitting element LED2 is driven by the second modulated signal stream to emit light. Then, optical signals of the light-emitting elements LED1, LED2 (specifically, the quantity of light reflected by an object OB) are detected by the light-receiving element 24. Thereafter, the position of the object OB (specifically, the distance and the tilt angle) is detected based on the quantity of the reflected light detected by the light-receiving element 24.

The execution modes of the position detecting device includes a distance detection mode for detecting the distance to the object OB. The distance detection mode will now be described.

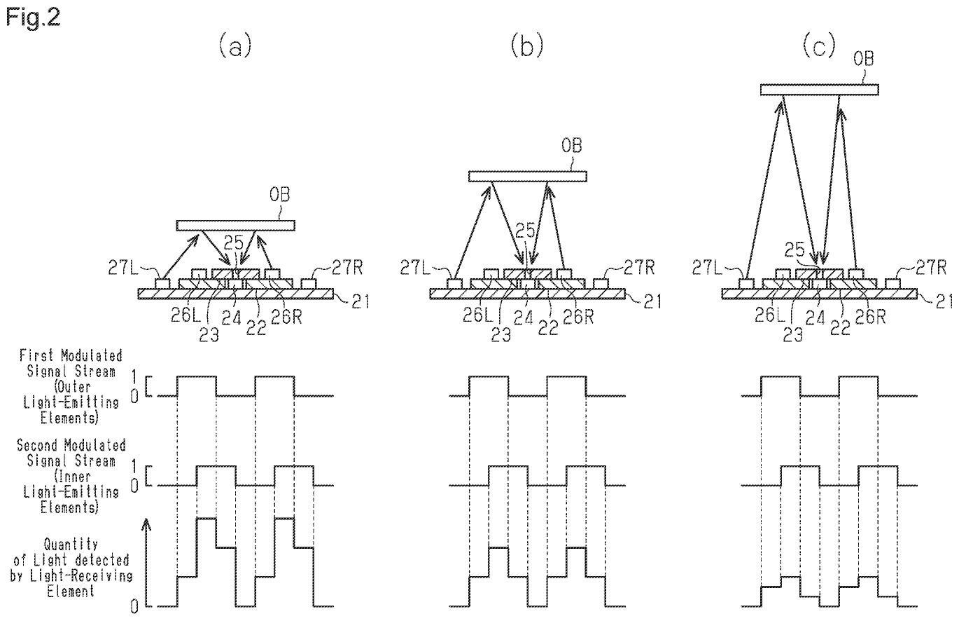

As shown in FIGS. 1 and 2, the distance detection mode uses the outer light-emitting elements 27L, 27R as the first light-emitting elements LED1, and uses the inner light-emitting elements 26L, 26R as the second light-emitting elements LED2. Specifically, the outer light-emitting elements 27L, 27R are driven by the first modulated signal stream to emit light, and the inner light-emitting elements 26L, 26R are driven by the second modulated signal stream to emit light. The distance detection mode is preferably configured such that the quantity of the optical signals emitted by the outer light-emitting elements 27L, 27R is greater than the quantity of the optical signals emitted by the inner light-emitting elements 26L, 26R. The ratio is set to, for example, 2:1.

When the distance to the object OB is relatively short as shown in section (a) of FIG. 2, the angle at which the optical signals of the outer light-emitting elements 27L, 27R (specifically, the light reflected by the object OB) is incident on the pinhole 25 (angle of incidence) is relatively large, and the optical path lengths are relatively long. Thus, the quantity of reflected light that is emitted by the outer light-emitting elements 27L, 27R and enters the light-receiving element 24, that is, a quantity VD1 of reflected light detected by the light-receiving element 24 is relatively small. The inner light-emitting elements 26L, 26R are closer to the light-receiving element 24 than the outer light-emitting elements 27L, 27R. Thus, the angle of incidence on the pinhole 25 of the optical signals of the inner light-emitting elements 26L, 26R (specifically, light reflected by the object OB) is smaller than the angle of incidence of the optical signals of the outer light-emitting elements 27L, 27R. Also, the optical path lengths are relatively short. Thus, the quantity of reflected light that is emitted by the inner light-emitting elements 26L, 26R and is incident on the light-receiving element 24, that is, a quantity VD2 of the reflected light detected by the light-receiving element 24 is relatively large.

In the position detecting device of the present embodiment, the quantity of the optical signals of the outer light-emitting elements 27L, 27R is set to be twice the quantity of the optical signals of the inner light-emitting elements 26L, 26R. However, when the distance to the object OB is relatively short, a detected value (the light quantity VD2) related to the optical signals of the inner light-emitting elements 26L, 26R is greater than a detected value (the light quantity VD1) related to the optical signals of the outer light-emitting elements 27L, 27R. In this case, a ratio RD of the light quantities VD1 and VD2 (RD=VD1/VD2) is less than 1. The shorter the distance to the object OB, the smaller the value of the ratio RD becomes.

When the distance to the object OB is increased so as to be an intermediate distance as shown in section (b) of FIG. 2, the difference between the angle of incidence of the inner light-emitting elements 26L, 26R and the angle of incidence of the outer light-emitting elements 27L, 27R is reduced. This reduces the difference between the detected value (the light quantity VD2) related to the optical signals of the inner light-emitting elements 26L, 26R and the detected value (the light quantity VD1) related to the optical signals of the outer light-emitting elements 27L, 27R. In this case, the ratio RD of the light quantities VD1 and VD2 (RD=VD1/VD2) approaches 1. In the example shown in section (b) of FIG. 2, the light quantities VD1 and VD2 are equal to each other, and the ratio RD of the light quantities VD1 and VD2 (RD=VD1/VD2) is 1.

When the distance to the object OB is further increased as shown in section (c) of FIG. 2, the difference between the angle of incidence of the inner light-emitting elements 26L, 26R and the angle of incidence of the outer light-emitting elements 27L, 27R is substantially 0. Accordingly, the relationship between the light quantities VD1 and VD2 approaches the relationship between the quantity of the optical signals emitted by the outer light-emitting elements 27L, 27R and the quantity of the optical signals emitted by the inner light-emitting elements 26L, 26R. That is, in this case, the detected value (the light quantity VD1) related to the outer light-emitting elements 27L, 27R approaches a value twice the detected value (light quantity VD2) of the optical signals of the inner light-emitting elements 26L, 26R, and the ratio RD of the light quantities VD1 and VD2 (RD=VD1/VD2) approaches 2. In the example shown in section (c) of FIG. 2, the light quantity VD1 is twice the light quantity VD2, and the ratio RD of the light quantities VD1 and VD2 (RD=VD1/VD2) is 2.

In the distance detection mode, a distance DIS to the object OB is detected based on the above-described relationship between the light quantities VD1, VD2 and the distance to the object OB. Specifically, the light quantities VD1, VD2 are detected, and the distance to the object OB is calculated (detected) based on the ratio RD of the light quantities VD1 and VD2 (RD=VD1/VD2).

The execution modes of the position detecting device includes a tilt angle detection mode for detecting a tilt angle of the object OB. The tilt angle detection mode will now be described.

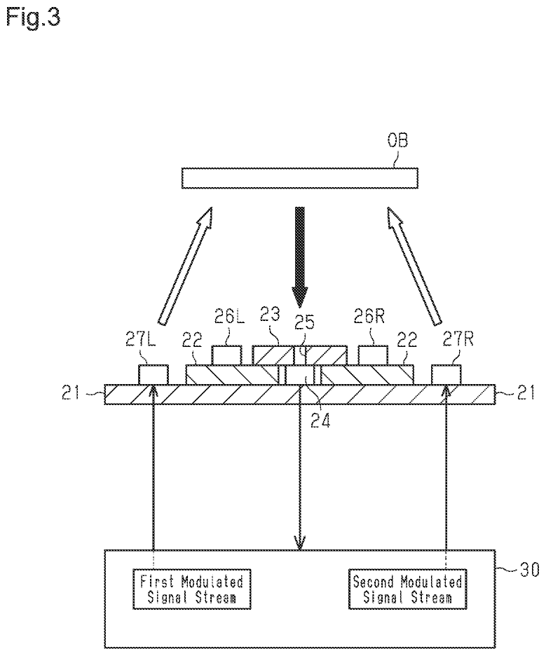

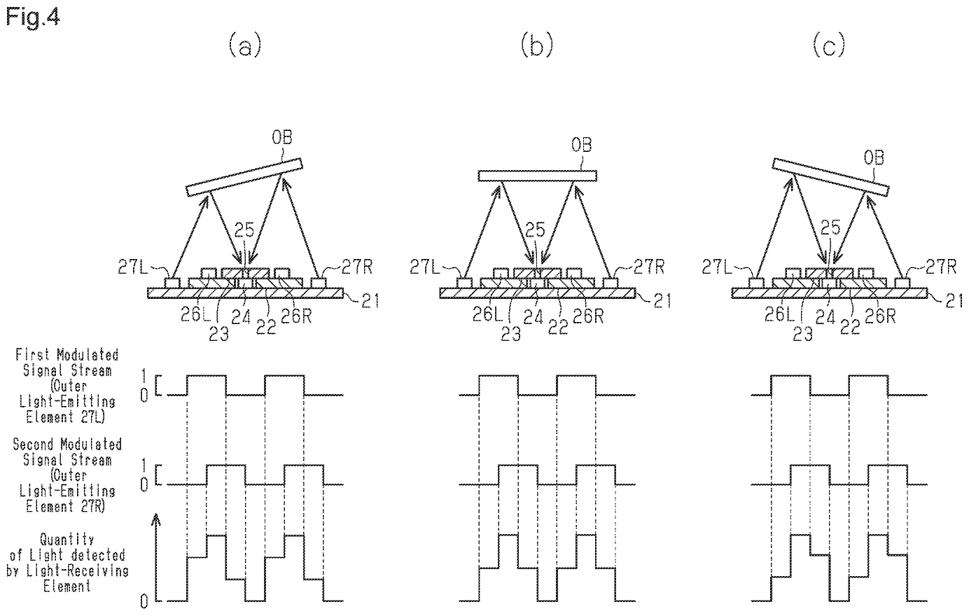

As shown in FIGS. 3 and 4, the tilt angle detection mode uses one of the outer light-emitting elements 27L, 27R (the outer light-emitting element 27L) as the first light-emitting element LED1, and uses the other one of the outer light-emitting elements 27L, 27R (the outer light-emitting element 27R) as the second light-emitting element LED2. Specifically, the outer light-emitting element 27L is driven by the first modulated signal stream to emit light. Then, after a phase delay of 90 degrees, the outer light-emitting element 27R is driven by the second modulated signal stream to emit light. In the tilt angle detection mode, the quantities of light emitted by the outer light-emitting elements 27L, 27R are set to be equal to each other.

When the object OB is inclined toward the outer light-emitting element 27L (to the left as viewed in FIG. 4) as shown in section (a) of FIG. 4, the distance between the outer light-emitting element 27L and the object OB is shorter than the distance between the outer light-emitting element 27R and the object OB. Accordingly, a path (optical path L1) of the light that is emitted by the outer light-emitting element 27L and is incident on the light-receiving element 24 is shorter than a path (optical path L2) of the light that is emitted by the outer light-emitting element 27R and is incident on the light-receiving element 24.

The quantity of the reflected light that is incident on the light-receiving element 24 is proportionate to the inverse square of the length of the optical path of the reflected light. Thus, as for the outer light-emitting element 27L, which has a relatively short optical path, a relatively large quantity of reflected light is detected by the light-receiving element 24. That is, a quantity VA1 of the light reflected by the object OB that is resultant of the optical signal emitted by the outer light-emitting element 27L is relatively large. In contrast, as for the outer light-emitting element 27R, which has a relatively long optical path, a relatively small quantity of reflected light is detected by the light-receiving element 24. That is, a quantity VA2 of the light reflected by the object OB that is resultant of the optical signal emitted by the outer light-emitting element 27R is relatively small.

Although the quantities of optical signals emitted by the outer light-emitting elements 27L and 27R are set to be equal to each other, the detected value (the light quantity VA1) related to the optical signal of the outer light-emitting element 27L is greater than the detected value (the light quantity VA2) related to the optical signal of the outer light-emitting element 27R. The ratio RA of the light quantities VA1 and VA2 (RA=VA1/VA2) is greater than 1 (RA>1). The larger the tilt angle of the object OB toward the outer light-emitting element 27L, the larger the value of the ratio RA becomes.

When the object OB faces the position detecting device squarely as shown in section (b) of FIG. 4 (tilt angle=0 degrees), the distances between the outer light-emitting elements 27L, 27R and the object OB are equalized. Thus, the path of the light that is emitted by the outer light-emitting element 27L and is incident on the light-receiving element 24 (optical path L1) is equal to the path of the light that is emitted by the outer light-emitting element 27R and is incident on the light-receiving element 24 (optical path L2). In this case, the detected value (the light quantity VA1) of the optical signal of the outer light-emitting element 27R is equal to the detected value (the light quantity VA2) of the optical signal of the outer light-emitting element 27R, and the ratio RA of the light quantities VA1 and VA2 (RA=VA1/VA2) becomes 1.

When the object OB is inclined toward the outer light-emitting element 27R (to the right as viewed in FIG. 4) as shown in section (c) of FIG. 4, the distance between the outer light-emitting element 27L and the object OB is longer than the distance between the outer light-emitting element 27R and the object OB. Accordingly, a path (optical path L1) of the light that is emitted by the outer light-emitting element 27L and is incident on the light-receiving element 24 is longer than a path (optical path L2) of the light that is emitted by the outer light-emitting element 27R and is incident on the light-receiving element 24.

Thus, as for the outer light-emitting element 27L, which has a relatively long optical path, a relatively small quantity of reflected light is detected by the light-receiving element 24. That is, a quantity VA1 of the light reflected by the object OB that is resultant of the optical signal emitted by the outer light-emitting element 27L is relatively small. In contrast, as for the outer light-emitting element 27R, which has a relatively short optical path, a relatively large quantity of reflected light is detected by the light-receiving element 24. That is, a quantity VA2 of the light reflected by the object OB that is resultant of the optical signal emitted by the outer light-emitting element 27R is relatively large.

Although the quantities of optical signals emitted by the outer light-emitting elements 27L and 27R are set to be equal to each other, the detected value (the light quantity VA1) related to the optical signal of the outer light-emitting element 27L is less than the detected value (the light quantity VA2) related to the optical signal of the outer light-emitting element 27R. In this case, the ratio RA of the light quantities VA1 and VA2 (RA=VA1/VA2) is less than 1 (RA<1). The larger the tilt angle of the object OB toward the outer light-emitting element 27R, the smaller the value of the ratio RA becomes.

In the tilt angle detection mode, a tilt angle of the object OB is detected based on the above-described relationship between the light quantities VA1, VA2 and the tilt angle of the object OB. Specifically, the light quantities VA1, VA2 are detected, and a tilt angle TIL of the object OB is calculated (detected) based on the ratio RA of the light quantities VA1 and VA2 (RA=VD1/VD2). The relationship between the optical paths L1 and L2 changes in accordance with the distance between the object OB and the position detecting device. Thus, the ratio RA changes in accordance with the distance. Accordingly, when detecting the tilt angle TIL of the object OB, the position detecting device of the present embodiment uses the distance DIS as a detection parameter, in addition to the ratio RA.

Hereinbelow, a detection circuit will be described that detects the quantity of light that has been emitted by the light-emitting elements 26L, 26R, 27L, 27R and reflected on the object OB (specifically, the value V1, which corresponds to the quantities VD1, VA1, and the value V2, which corresponds to the quantities VD2, VA2). The detection circuit includes a microprocessor and is configured to execute various processes by executing software using the microprocessor.

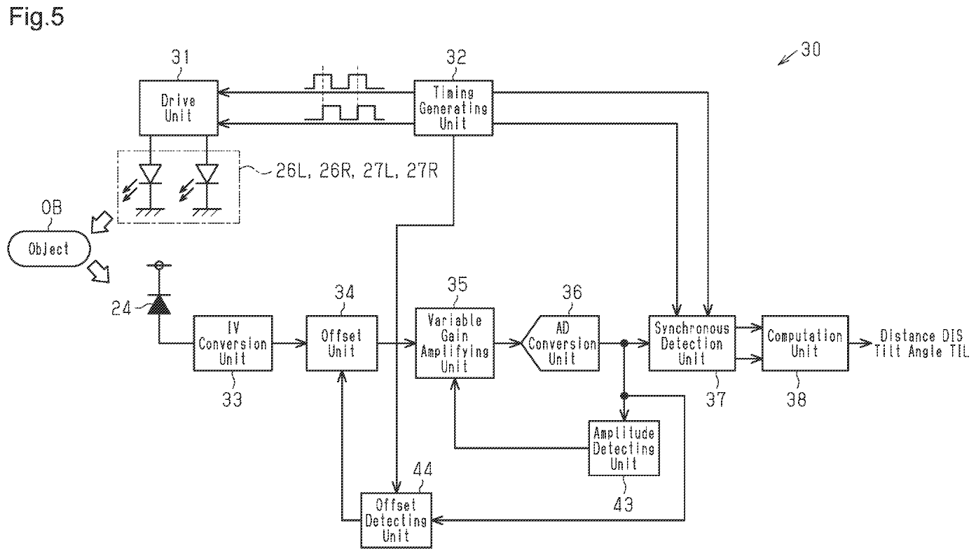

As shown in FIG. 5, the detection circuit 30 includes a configuration for emitting optical signals, which includes the light-emitting elements 26L, 26R, 27L, 27R, a drive unit 31, which drives the light-emitting elements 26L, 26R, 27L, 27R to emit light, and a timing generating unit 32, which generates the first modulated signal stream and the second modulated signal stream.

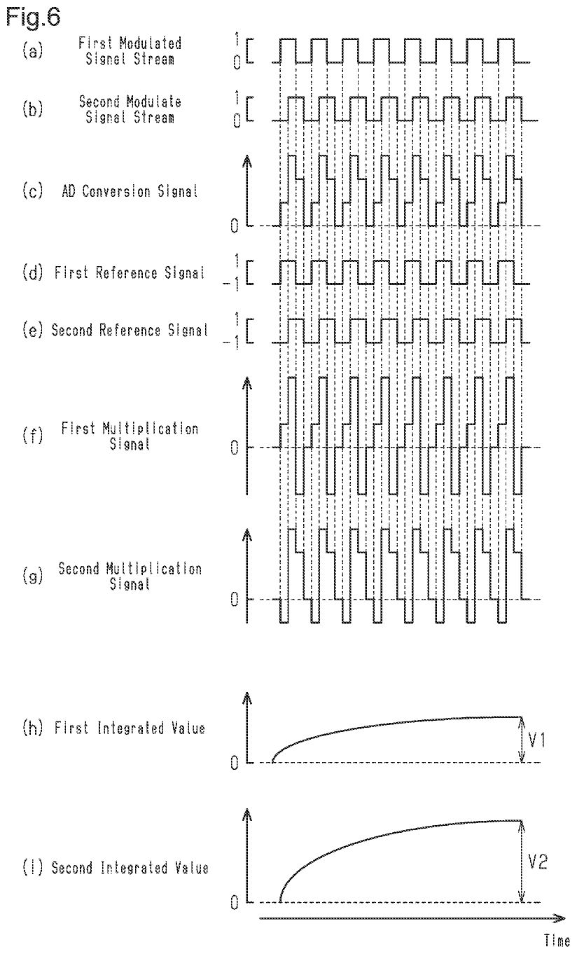

As shown in FIG. 6, the timing generating unit 32 generates two types of modulated signal streams including signals having rectangular waves over a specific level of time. The phases of the modulated signal streams are displaced from each other by 90 degrees. The duty cycle of the modulated signal streams is 50%. The modulated signal streams include a first modulated signal stream (section (a) in FIG. 6)) and a second modulated signal stream (section (b) in FIG. 6).

As shown in FIG. 5, the timing generating unit 32 outputs the first modulated signal stream and the second modulated signal stream to the drive unit 31. The drive unit 31 selectively causes the light-emitting elements 26L, 26R, 27L, 27R to emit light based on the first modulated signal stream and the second modulated signal stream. In the distance detection mode, the inner light-emitting elements 26L, 26R are driven to emit light based on the first modulated signal stream, and the outer light-emitting elements 27L, 27R are driven to emit light based on the second modulated signal stream. In the tilt angle detection mode, the outer light-emitting element 27L is driven to emit light based on the first modulated signal stream, and the outer light-emitting element 27R is driven to emit light based on the second modulated signal stream.

The detection circuit 30 includes a configuration for detecting the quantity of the reflected light, which includes the light-receiving element 24, an IV conversion unit 33, an offset unit 34, a variable gain amplifying unit 35, an AD conversion unit 36, a synchronous detection unit 37, and a computation unit 38, which are arranged in order from the light-receiving element 24. In the present embodiment, the synchronous detection unit 37 and the computation unit 38 correspond to a position detecting unit.

The light-receiving element 24 is configured to output a current signal that corresponds to the quantity of reflected light that is incident on the light-receiving element 24.

The IV conversion unit 33 receives the current signal output from the light-receiving element 24. The IV conversion unit 33 converts the input current signal into a voltage signal and outputs the voltage signal.

The offset unit 34 receives the voltage signal (IV conversion signal) output from the IV conversion unit 33. The offset unit 34 offsets the direct-current voltage level of the IV conversion signal by a specific level (target offset level), and outputs the IV conversion signal. Control for setting the offset level of the offset unit 34 will be described later.

The variable gain amplifying unit 35 receives a voltage signal (an offset signal) output from the offset unit 34. The variable gain amplifying unit 35 is configured to change the amplification factor of an amplifier. The position detecting device of the present embodiment changes the gain of the variable gain amplifying unit 35 in order to adjust the amplitude of a voltage signal (variable gain signal) output from the variable gain amplifying unit 35 to an appropriate value. Control for variably setting the gain using the variable gain amplifying unit 35 will be described below.

The AD conversion unit 36 is configured to convert an analog signal into a digital signal. The AD conversion unit 36 receives the variable gain signal output from the variable gain amplifying unit 35. The AD conversion unit 36 converts the variable gain signal into a digital signal (16-bit signal (65536 steps) in the present embodiment) and outputs the digital signal. As shown in section (c) in FIG. 6, the signal output from the AD conversion unit 36 (AD conversion signal) has a value obtained by superimposing the value V1 and the value V2. The value V1 corresponds to the quantity of the reflected light (the light quantities VD1, VA1) related to the optical signal emitted by the first light-emitting element LED1 based on the first modulated signal stream. The value V2 corresponds to the quantity of the reflected light (the light quantities VD2, VA2) related to the optical signal emitted by the second light-emitting element LED2 based on the second modulated signal stream.

A generally-used anti-aliasing filter may be provided at a stage prior to the AD conversion unit 36, in order to suppress the occurrence of aliasing during AD conversion.

The synchronous detection unit 37 includes a two-phase lock-in amplifier.

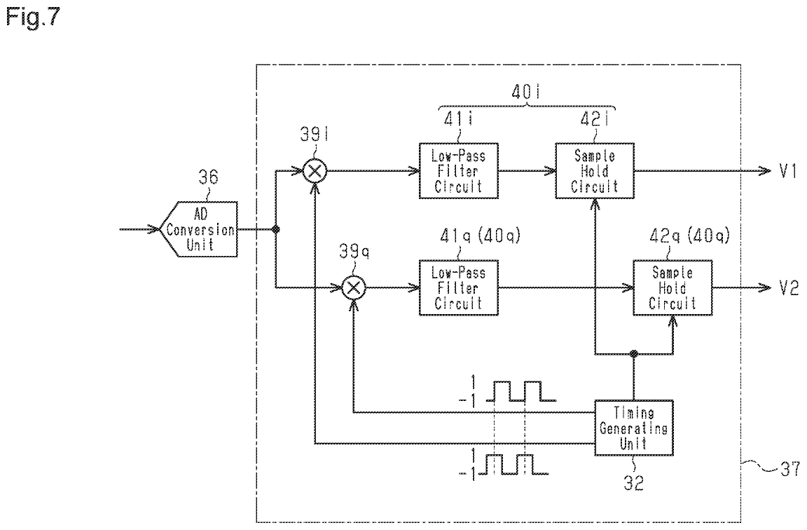

As shown in FIG. 7, the synchronous detection unit 37 includes multipliers 39i, 39q and integrators 40i, 40q. The multipliers 39i, 39q multiply a measurement signal (AD conversion signal) by a reference signal (the first modulated signal stream or the second modulated signal stream). The integrators 40i, 40q integrate a signal value output from the multipliers 39i, 39q (a first multiplication signal or a second multiplication signal). The integrators 40i, 40q include low-pass filter circuits 41i, 41q and sample hold circuits 42i, 42q.

The following describes the process through which the synchronous detection unit 37 calculates the value V1 corresponding to the quantity of reflected light (the light quantities VD1, VA1) related to the optical signal emitted by the first light-emitting element LED1 based on the first modulated signal stream. First, the multiplier 39i multiplies the AD conversion signal (section (c) in FIG. 6), which is a measurement signal, by the first modulated signal stream, which is a reference signal (specifically, a first reference signal shown in section (d) in FIG. 6). The first multiplication signal output from the multiplier 39i (section (f) in FIG. 6) is integrated by the integrator 40i as shown in section (h) in FIG. 6. The value integrated by the integrator 40i is output as the value V1.

The following describes the process through which the synchronous detection unit 37 calculates the value V2 corresponding to the quantity of the reflected light (the light quantities VD2, VA2) related to the optical signal emitted based on the second modulated signal stream. First, the multiplier 39q multiplies the AD conversion signal (section (c) in FIG. 6), which is a measurement signal, by the second modulated signal stream, which is a reference signal (specifically, a second reference signal shown in section (e) in FIG. 6). The second multiplication signal output from the multiplier 39q (section (g) in FIG. 6) is integrated by the integrator 40q as shown in section (i) in FIG. 6. The value integrated by the integrator 40q is output as the value V2.

The computation unit 38 calculates and outputs the distance DIS to the object OB through a computation process based on the values V1, V2, and calculates and outputs the tilt angle TIL of the object OB through a computation process based on the distance DIS and the value V1, V2. Specifically, the distance detection mode calculates the distance DIS to the object OB, from a relationship (for example, arithmetic expressions and operation tables) that is stored in the computation unit 38 in advance and based on the value V1 (the light quantity VD1) and the value V2 (the light quantity VD2). The tilt angle detection mode calculates the tilt angle TIL of the object OB, from a relationship (for example, arithmetic expressions and operation tables) that is stored in the computation unit 38 in advance and based on the value V1 (the light quantity VA1), the value V2 (the light quantity VA2), and the distance DIS. In the present embodiment, the synchronous detection unit 37 and the computation unit 38 each correspond to a digital signal processing unit, which performs a computation process on the digital signal converted by the AD conversion unit 36.

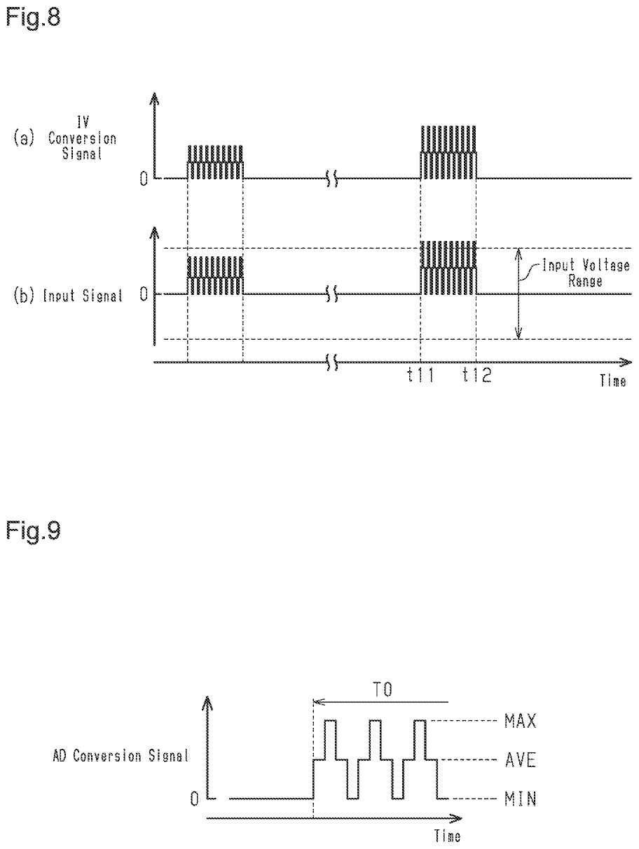

The signal value of a current signal output from the light-receiving element 24 varies from moment to moment depending on the quantity of reflected light that is incident on the light-receiving element 24. Thus, if a current signal output from a light-receiving element (specifically, the IV conversion signal output from the IV conversion unit 33) is simply input to the AD conversion unit 36, the following drawbacks may be caused. As in an example illustrated in FIG. 8, when the quantity of the reflected light is relatively large (from a point in time t11 to a point in time t12), the maximum value of the analog signal input to the AD conversion unit 36 exceeds the maximum value of the input voltage range (for example, ±600 mV) of the AD conversion unit 36. The analog signal thus cannot be properly converted, and the position detection may not be performed normally. In a case in which the gain of the AD conversion unit 36 is reduced, a small quantity of reflected light reduces the value of the analog signal input to the AD conversion unit 36 in relation to the input voltage range of the AD conversion unit 36. In this case, the influence of the quantization noise of the AD conversion unit 36 reduces the SNR of the AD conversion unit 36. This may reduce the accuracy of the position detection by the position detecting device.

Taking the above into consideration, the position detecting device of the present embodiment includes the offset unit 34, which is located between the IV conversion unit 33 and the variable gain amplifying unit 35 as shown in FIG. 5, and offsets the IV conversion signal output from the IV conversion unit 33. The offset unit 34 performs intensity-modulation in the modulation period T0 using the first modulated signal stream and the second modulated signal stream. In the modulation period T0, the IV conversion signal is offset such that the average of the maximum value and the minimum value of the electric signal (analog signal) input to the AD conversion unit 36 agrees with the median of the input voltage range (for example, ±600 mV). The direct-current voltage level is changed, accordingly.

A configuration for offsetting an electric signal using the offset unit 34 will now be described.

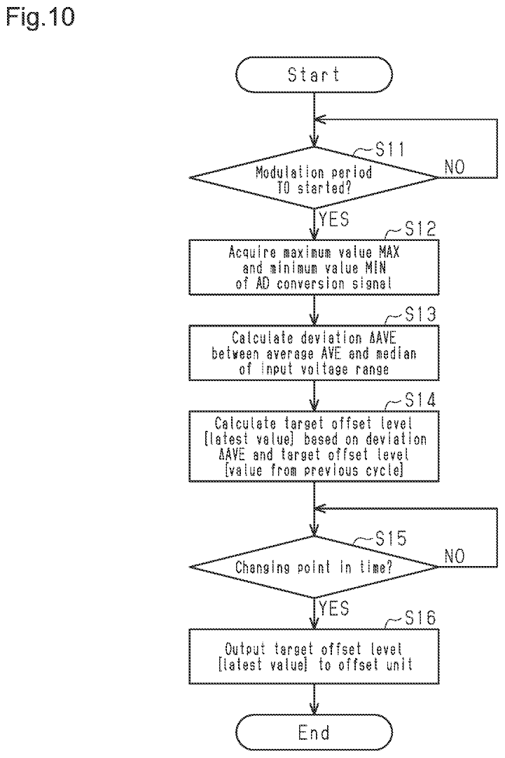

The detection circuit 30 includes an offset detecting unit 44. In the present embodiment, the offset detecting unit 44 executes the following process each time the modulation period T0 starts (step S11: YES) as shown in FIG. 10.

First, the offset detecting unit 44 acquires the maximum value MAX and the minimum value MIN of the AD conversion signal output from the AD conversion unit 36 in the modulation period T0 (step S12).

As shown in FIG. 9, in the modulation period T0, a signal value of the AD conversion signal when the light-emitting elements that are driven by the first modulated signal stream to emit light and the light-emitting elements that are driven by the second modulated signal stream to emit light are lit simultaneously corresponds to the maximum value (MAX) of the signal value of the AD conversion signal. Also, in the modulation period T0, a signal value of the AD conversion signal when the light-emitting elements that are driven by the first modulated signal stream to emit light and the light-emitting elements that are driven by the second modulated signal stream to emit light are turned off simultaneously corresponds to the minimum value (MIN) of the signal value of the AD conversion signal. Taking the above into consideration, the present embodiment acquires, as the maximum value MAX, the AD conversion signal at the first simultaneous lighting in the modulation period T0. Also, the present embodiment acquires, as the minimum value MIN, the AD conversion signal at the first simultaneous turn-off in the modulation period T0.

Thereafter, as shown in FIG. 10, based on the maximum value MAX and the minimum value MIN, a deviation ΔAVE between the median of the input voltage range of the AD conversion unit 36 and an average AVE (AVE=(MAX+MIN)/2) of the maximum value MAX and the minimum value MIN is calculated (step S13).

Then, based on the deviation ΔAVE and the current target offset level [value from previous cycle], a control target value of the level of offset to be made by the offset unit 34 (target offset level [latest value]) is calculated (step S14).

In the present embodiment, the target offset level [latest value] is calculated to be a value corresponding to an offset level that allows the average AVE of the maximum value MAX and the minimum value MIN to agree with the median of the input voltage range of the AD conversion unit 36. This calculation is performed taking into consideration a gain setting value of the variable gain amplifying unit 35. In the present embodiment, a relationship (arithmetic expression) that allows the calculation of the target offset level [latest value] is obtained and stored in the offset detecting unit 44 in advance. Using the relationship, the offset detecting unit 44 calculates the target offset level [latest value].

Thereafter, at a specific changing point in time in a period during which neither the first modulated signal stream nor the second modulated signal stream is set, that is, in a period from when the modulation period T0 ends to when the subsequent modulation period T0 starts (step S15: YES), the target offset level [latest value] is output to the offset unit 34 (step S16). At this time, the offset unit 34 changes the actual offset level such that the actual offset level agrees with the input target offset level [latest value].

Operational advantages achieved by offsetting an electric signal using the offset unit 34 will now be described.

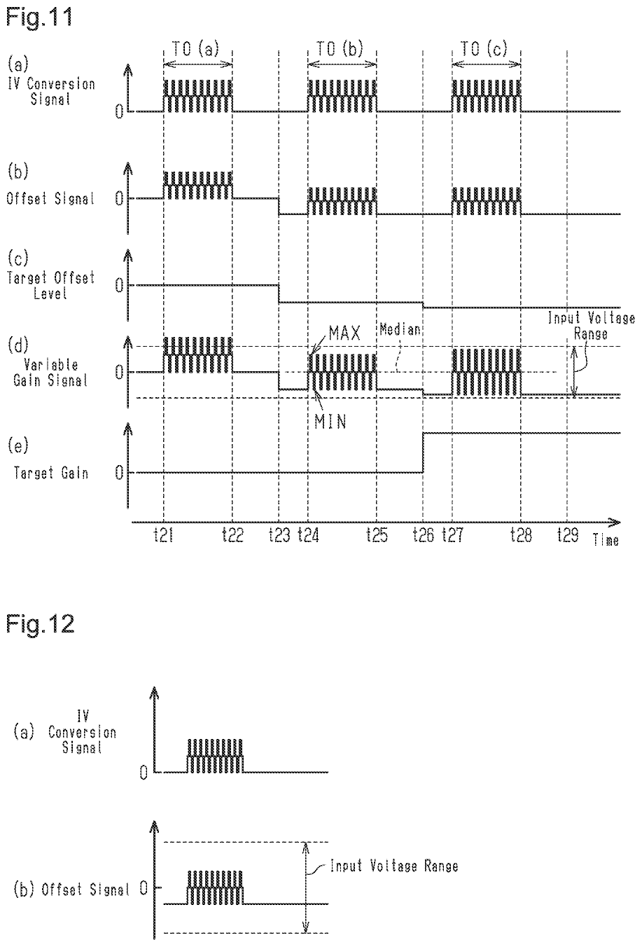

In the present embodiment, as shown in FIG. 11, the maximum value MAX and the minimum value MIN of the AD conversion signal (refer to section (c) in FIG. 6) in a modulation period T0(a) (from a point in time t21 to a point in time t22) are detected. Based on the maximum value MAX and the minimum value MIN, a control target value (target offset level) related to the offset level by the offset unit 34 is calculated.

The offset level by the offset unit 34 is changed based on the target offset level at a specific changing point in time (point in time t23) after the modulation period T0 (from the point in time t21 to the point in time t22) and before the subsequent modulation period T0(b) (from a point in time t24 to a point in time t25). Accordingly, the offset level of the offset unit 34 is changed to an appropriate value (a relatively low value in this example) prior to the subsequent input of the IV conversion signal to the offset unit 34.

In the present embodiment, the offset unit 34 offsets the IV conversion signal such that the average AVE of the maximum value MAX and the minimum value MIN of the AD conversion signal output from the AD conversion unit 36 agrees with the median of the input voltage range of the AD conversion unit 36 (0 V in the present embodiment). When an appropriate offset level is not set for the IV conversion signal, the analog signal input to the AD conversion unit 36 exceeds the input voltage range of the AD conversion unit 36 as illustrated in the modulation period T0(a). Also, the voltage amplitude has values unevenly spread above and below the median of the input voltage range. However, when an appropriate offset level is set, the analog signal input to the AD conversion unit 36 is confined within the input voltage range of the AD conversion unit 36 as illustrated in the modulation period T0(b). Also, the voltage amplitude has values evenly spread above and below the median of the input voltage range.

This increases the amplitude of the analog signal input to the AD conversion unit 36 (specifically, the variable gain signal shown in section (d) in FIG. 11) in relation to the input voltage range of the AD conversion unit 36. Accordingly, the present embodiment reduces the influence of the quantization noise of the AD conversion unit 36 and increases the SNR of the AD conversion unit 36, allowing the position detecting device to perform accurate position detection.

The position detecting device of the present embodiment performs such control for changing the offset level each time the modulation period T0 is set at specific intervals (from the point in time t21 to the point in time t24, from the point in time t24 to the point in time t27, and after the point in time t27).

In the position detecting device of the present embodiment, the current signal output from the light-receiving element 24, the IV conversion signal, and the offset signal, are changed in accordance with the quantity of the reflected light that is incident on the light-receiving element 24. Therefore, if the AD conversion unit 36 performs signal conversion with a constant gain, the following drawbacks may be caused. That is, as in an example illustrated in FIG. 12, when the quantity of reflected light that is incident on the light-receiving element 24 is small, the amplitude of the electric signal (the offset signal in this example) input to the AD conversion unit 36 is small in relation to the input voltage range of the AD conversion unit 36. In this case, the influence of the quantization noise of the AD conversion unit 36 may reduce the accuracy of the position detection by the position detecting device.

Taking the above into consideration, the position detecting device of the present embodiment includes the variable gain amplifying unit 35 between the offset unit 34 and the AD conversion unit 36 as shown in FIG. 5. The variable gain amplifying unit 35 is controlled such that the amplitude of the electric signal input to the AD conversion unit 36 has a value within a predetermined specific range S (approximately 90% of the input voltage range of the AD conversion unit 36 in the present embodiment).

The following describes a configuration for changing the gain of the variable gain amplifying unit 35 in detail.

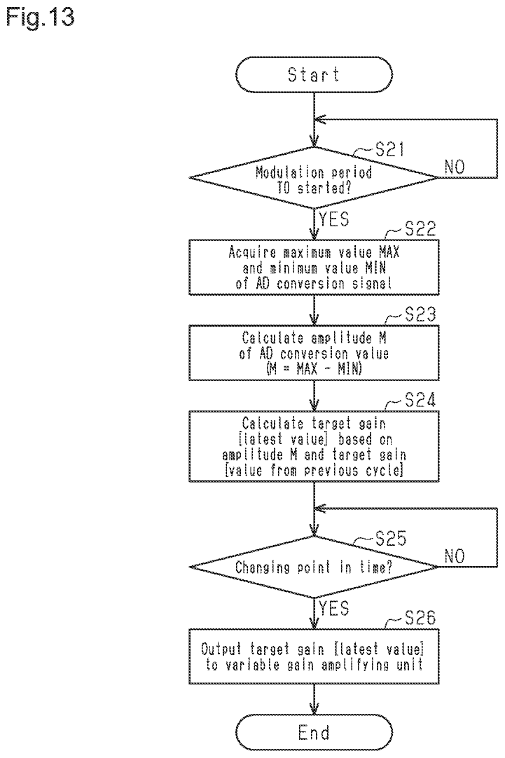

The detection circuit 30 includes an amplitude detecting unit 43, which detects an amplitude M of the AD conversion signal output from the AD conversion unit 36. In the present embodiment, the amplitude detecting unit 43 executes the following process each time the modulation period T0 starts (step S21: YES) as shown in FIG. 13.

First, the amplitude detecting unit 43 acquires the maximum value MAX and the minimum value MIN of the AD conversion signal output from the AD conversion unit 36 in the modulation period T0 (step S22). The present embodiment acquires, as the maximum value MAX, the AD conversion signal at the first simultaneous lighting in the modulation period T0. Also, the present embodiment acquires, as the minimum value MIN, the AD conversion signal at the first simultaneous turn-off in the modulation period T0.

Then, a difference value (MAX−MIN) between the maximum value MAX and the minimum value MIN is calculated as the amplitude M of the AD conversion signal (step S23).

Thereafter, based on the amplitude M of the AD conversion signal and the current gain of the variable gain amplifying unit 35 (specifically, the target gain [value from previous cycle]), a control target value of the gain (target gain [latest value]) is calculated (step S24). In the position detecting device of the present embodiment, the amplitude detecting unit 43 stores in advance a relationship among a gain that causes the amplitude M of the AD conversion signal to fall within the specific range S of the input voltage range of the AD conversion unit 36 (target gain [latest value]), the amplitude M of the AD conversion signal, and the gain of the variable gain amplifying unit 35 (target gain [value from previous cycle]). Using the relationship, the amplitude detecting unit 43 calculates the target gain [latest value].

Thereafter, at a specific changing point in time in a period during which neither the first modulated signal stream nor the second modulated signal stream is set, that is, in a period from when the modulation period T0 ends to when the subsequent modulation period T0 starts (step S25: YES), the target gain [latest value] is output to the variable gain amplifying unit 35 (step S26). At this time, the variable gain amplifying unit 35 changes the actual gain such that the actual gain agrees with the input target gain [latest value] and the actual gain.

Operational advantages achieved by changing the gain of the variable gain amplifying unit 35 will now be described.

In an example shown in FIG. 11, the gain of the variable gain amplifying unit 35 is relatively less than an appropriate value during the modulation period T0(b) (from the point in time t24 to the point in time t25). Thus, the amplitude of the variable gain signal output from the variable gain amplifying unit 35 is reduced to approximately 50% in relation to the input voltage range of the AD conversion unit 36. In the position detecting device of the present embodiment, the modulation period T0 is repeatedly set in short cycles. Thus, if position detection for the same object OB is performed continuously, the above-mentioned differences would be smaller than in the example shown in FIG. 11.

In the position detecting device of the present embodiment, the maximum value MAX and the minimum value MIN of the AD conversion signal (refer to section (c) in FIG. 6) in the modulation period T0(b) (from the point in time t24 to the point in time t25) are detected. Based on the maximum value MAX and the minimum value MIN, the control target value (target gain) related to the gain of the variable gain amplifying unit 35 is calculated. This calculation is performed taking into consideration an offset setting value of the offset unit 34.

The gain of the variable gain amplifying unit 35 is changed based on the target gain at a specific point in time (the point in time t26) after the modulation period T0(b) (from the point in time t24 to the point in time t25) and before the subsequent modulation period T0 (from the point in time t27 to the point in time t28).

Accordingly, the gain of the variable gain amplifying unit 35 is changed to an appropriate value (a relatively large value in this example) prior to the subsequent input of the offset signal to the variable gain amplifying unit 35. Thus, when the offset signal is input to the variable gain amplifying unit 35 in the modulation period T0(c) (from the point in time t27 to the point in time t28), the amplitude of the variable gain signal output from the variable gain amplifying unit 35, and thus the amplitude M of the AD conversion signal output from the AD conversion unit 36, fall within (or near) the predetermined specific range S.

The position detecting device of the present embodiment performs such control for changing the gain of the variable gain amplifying unit 35 each time the modulation period T0 is set at specific intervals (from the point in time t21 to the point in time t24, from the point in time t24 to the point in time t27, and after the point in time t27).

The position detecting device of the present embodiment changes the IV conversion signal and the offset signal in accordance with the quantity of the reflected light that is incident on the light-receiving element 24. However, the amplitude of the variable gain signal input to the AD conversion unit 36 is adjusted through changing the gain of the variable gain amplifying unit 35, such that the amplitude falls within the input voltage range of the AD conversion unit 36, preferably, within 60% to 90% of the input voltage range. This minimizes the influence of quantization noise of the AD conversion unit 36, allowing the position detecting device to perform accurate position detection.

As described above, the present embodiment provides the following advantages.

(1) In the modulation period T0, the offset unit 34 offsets the IV conversion signal such that the average of the maximum value and the minimum value of the electric signal input to the AD conversion unit 36 agrees with the median of the input voltage range of the AD conversion unit 36. Accordingly, the average is maintained within the input voltage range of the AD conversion unit 36, allowing accurate position detection to be performed. Also, the influence of the quantization noise is contained within the input voltage range of the AD conversion unit 36. This increases the SNR. Accordingly, the position detecting accuracy of the position detecting device is improved.

(2) The maximum value MAX of the AD conversion signal can be set to a signal value of the AD conversion signal at simultaneous lighting of the light-emitting elements that are driven by the first modulated signal stream to emit light and the light-emitting elements that are driven by the second modulated signal stream to emit light. Also, the minimum value MIN of the AD conversion signal can be set to a signal value of the AD conversion signal at simultaneous turn-off of the light-emitting elements that are driven by the first modulated signal stream to emit light and the light-emitting elements that are driven by the second modulated signal stream to emit light. Thus, the signal value (maximum value MAX) of the AD conversion signal at simultaneous lighting and the signal value (minimum value MIN) of the AD conversion signal at simultaneous turn-off can be detected without providing a peak hold circuit or a bottom hold circuit that includes a time constant for detection. It is also possible to set the offset level using the offset unit 34 based on these signal values. Also, when calculating the target offset level, the signal value (MAX) of the AD conversion signal at the first simultaneous lighting in the modulation period T0 and the signal value (MIN) of the AD conversion signal at the first simultaneous turn-off in the modulation period T0 are detected and used. This allows the target offset level to be readily calculated without delay after the AD conversion signal starts being output.

(3) The points in time at which the offset level of the offset unit 34 is changed are set in a period from when the modulation period T0 ends to when the modulation period T0 is started. Thus, in the same modulation period T0, the offset level is maintained at a constant value without being changed. This prevents the occurrence of detection errors due to a change in the offset level during the modulation period T0, allowing the position detecting device to perform accurate position detection.

(4) The gain of the variable gain amplifying unit 35 is controlled such that the amplitude of the electric signal input to the AD conversion unit 36 has a value within the predetermined specific range S. This minimizes the influence of quantization noise, allowing the position detecting device to perform accurate position detection.

(5) The difference value (MAX−MIN) between the signal value (MAX) of the AD conversion signal when the first light-emitting element LED1 and the second light-emitting element LED2 are simultaneously lit and the signal value (MIN) of the AD conversion signal when the first light-emitting element LED1 and the second light-emitting element LED2 are simultaneously turned off is detected as the amplitude M of the AD conversion signal. Therefore, the amplitude M of the AD conversion signal can be obtained from the electric signal at simultaneous lighting and the electric signal at simultaneous turn-off without providing a peak hold circuit or a bottom hold circuit that includes a time constant for detection. Also, when calculating the amplitude M, the signal value (MAX) of the AD conversion signal at the first simultaneous lighting in the modulation period T0 and the signal value (MIN) of the AD conversion signal at the first simultaneous turn-off in the modulation period T0 are detected and used. Thus, the amplitude M of the AD conversion signal is detected in a short period immediately after the beginning of output of the AD conversion signal.

(6) The points in time at which the gain of the variable gain amplifying unit 35 is changed are set in a period from when the modulation period T0 ends to when the modulation period T0 is started. Thus, in the same modulation period T0, the gain of the variable gain amplifying unit 35 is maintained at a constant value without being changed. This prevents the occurrence of detection errors due to a change in the gain during the modulation period T0, allowing the position detecting device to perform accurate position detection.

The above-described embodiment may be modified as follows. The above-described embodiment and the following modifications can be combined as long as the combined modifications remain technically consistent with each other.

The variable gain amplifying unit 35 and the amplitude detecting unit 43 may be omitted, so that the offset signal output from the offset unit 34 is directly input to the AD conversion unit 36.

The method for calculating the amplitude M of the AD conversion signal can be changed. For example, it is possible to detect the signal value (MAX) of the AD conversion signal at simultaneous lighting during the modulation period T0, and the signal value (MIN) of the AD conversion signal at simultaneous turn-off during the modulation period T0, and calculate the difference value between these signal values as the amplitude M of the AD conversion signal.

The point in time to change the gain of the variable gain amplifying unit 35 may be changed. For example, the gain of the variable gain amplifying unit 35 may be changed at a specific point in time in the modulation period T0.

The signal value (MAX) of the AD conversion signal at simultaneous lighting during the modulation period T0, and the signal value (MIN) of the AD conversion signal at simultaneous turn-off during the modulation period T0 may be detected and used as parameters for calculating the target offset level.

In the above-described embodiments, the target offset level [latest value] is calculated to be a value corresponding to an offset level that allows the average AVE of the maximum value MAX and the minimum value MIN to agree with the median of the input voltage range of the AD conversion unit 36. The present disclosure is not limited to this. For example, any value can be calculated as the target offset level [latest value] as long as the calculated value corresponds to an offset level that allows the average AVE to approach the median of the input voltage range. This configuration also allows the input voltage range of the AD conversion unit 36 to be used evenly and effectively as compared to a case in which the IV conversion signal is input to the AD conversion unit 36 without being offset.

It is possible to calculate, as the target offset level [latest value], a value corresponding to an offset level that allows a signal value (intermediate value) of an electric signal that is input to the AD conversion unit 36 when only one of the first light-emitting element LED1 and the second light-emitting element LED2 is lit, to agree with the median of the input voltage range of the AD conversion unit 36.

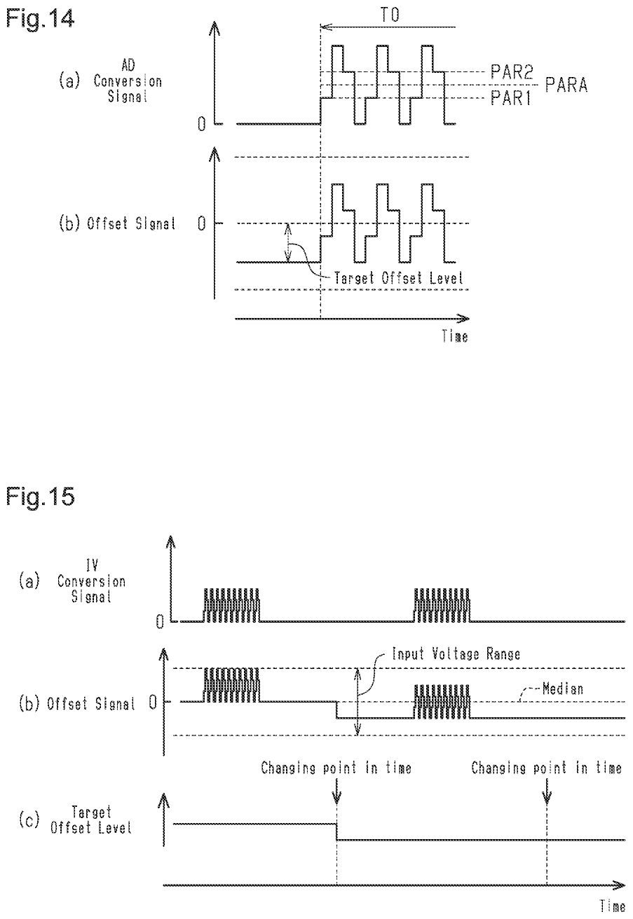

This configuration is capable of calculating the target offset level [latest value] in the following manner. First, as in an example illustrated in FIG. 14, the offset detecting unit 44 acquires intermediate values PAR1 and PAR2 of the AD conversion signal output from the AD conversion unit 36 during the modulation period T0. As the intermediate values PAR1 and PAR2, signal values of the electric signal input to the AD conversion unit 36 when only one of the first light-emitting element LED1 and the second light-emitting element LED2 is lit are acquired. The offset detecting unit 44 calculates a deviation ΔPAR between an average PARA of the intermediate values PAR1 and PAR2, and the median of the input voltage range of the AD conversion unit 36. Then, based on the deviation ΔPAR and the current target offset level [value from previous cycle], the offset detecting unit 44 calculates a target offset level [latest value] using a relationship (arithmetic expression) that is stored in advance.

As shown in FIG. 15, the above-described configuration offsets an analog signal input to the AD conversion unit 36 in a direction that reduces the difference between the median of the input voltage range of the AD conversion unit 36 and the median of the fluctuation range of the analog signal. This configuration allows the input voltage range of the AD conversion unit 36 to be used evenly and effectively as obvious in section (b) of FIG. 15, unlike a case in which the IV conversion signal is input to the AD conversion unit 36 without being offset. Also, in the above-described configuration, the target offset level is calculated based on the intermediate values PAR. Thus, even if the maximum value MAX and the minimum value MIN exceed the input voltage range of the AD conversion unit 36, the control will continue without failing. Accordingly, a stable operation is achieved.

In the above-described configuration, the target offset level [latest value] does not necessarily need to be calculated as a value corresponding to an offset level that allows the average PARA of the intermediate values PAR1 and PAR2 and the median of the input voltage range of the AD conversion unit 36 to agree with each other. However, any value can be calculated as long as the calculated value corresponds to an offset level that allows the intermediate values PAR to approach the median of the input voltage range. As the target offset level [latest value], a value may be calculated that corresponds to an offset level that allows the intermediate value PAR1 and the median of the input voltage range of the AD conversion unit 36 to agree with each other. Alternatively, a value may be calculated that corresponds to an offset level that allows the intermediate value PAR2 and the median of the input voltage range of the AD conversion unit 36 to agree with each other. This configuration allows the input voltage range of the AD conversion unit 36 to be used effectively while allowing the voltage amplitude to have values evenly spread above and below the median of the input voltage range, as compared to a case in which the IV conversion signal is input to the AD conversion unit 36 without being offset.

The point in time to change the offset level of the offset unit 34 may be changed. For example, the offset level by the offset unit 34 may be changed in a specific point in time during the modulation period T0. Specifically, the offset level may be changed by outputting the target offset level to the offset unit 34 immediately after detection of offset is completed in the first modulation cycle at the beginning of the modulation period T0.

The above-described embodiment may be applied to a position detecting device that includes multiple groups of light-emitting elements arranged on the same straight line. Such a position detecting device may have two groups of four light-emitting elements 26L, 26R, 27L, 27R, in which lines along which the light-emitting elements are arranged are orthogonal to each other.

The position detecting device does not necessarily need to have a base of a three-layer structure. For example, the position detecting device may include a single layer structure in which the light-receiving element 24 is mounted on the lower surface (back surface) of the upper layer base 23, and light is received on the mounted surface of the light-receiving element 24. In this case, the light-receiving element 24 is preferably potted in a sealing material having a light shielding property, so as to avoid influence of stray light onto the back surface.

In the position detecting device of the above-described embodiment, the variable gain amplifying unit 35 is arranged in the stage subsequent to the offset unit 34. However, the positional relationship may be reversed, so that the offset unit 34 may be arranged in the stage subsequent to the variable gain amplifying unit 35.

The configuration according to the above-described embodiment may be applied to a position detecting device that outputs, as drive signals for driving light-emitting elements, two types of modulated signal streams (a first modulated signal stream and a second modulated signal stream) of which the phases are displaced from each other by an angle other than 90 degrees. Further, the configuration according to the above-described embodiment may be applied to a position detecting device that outputs two types of modulated signal streams (a first modulated signal stream and a second modulated signal stream), with which a state in which only the first light-emitting elements emit light and a state in which the second light-emitting elements emit light are repeated alternately.

The configuration according to the above-described embodiment is not limited to a position detecting device that detects both the position and the tilt angle of the object OB, but may be applied to a position detecting device that detects only one of the position and the tilt angle of the object OB.

Various changes in form and details may be made to the examples above without departing from the spirit and scope of the claims and their equivalents. The examples are for the sake of description only, and not for purposes of limitation. Descriptions of features in each example are to be considered as being applicable to similar features or aspects in other examples. Suitable results may be achieved if sequences are performed in a different order, and/or if components in a described system, architecture, device, or circuit are combined differently, and/or replaced or supplemented by other components or their equivalents. The scope of the disclosure is not defined by the detailed description, but by the claims and their equivalents. All variations within the scope of the claims and their equivalents are included in the disclosure.

What is claimed is:

1. A position detecting device, comprising:
light-emitting units that emit optical signals that are intensity-modulated using modulated signal streams of different phases;
a light-receiving unit that receives reflected light and converts the reflected light into an analog signal, the reflected light being the optical signal reflected by an object;
an AD conversion unit that converts the analog signal into a digital signal;
a position detecting unit that detects a position of the object based on the digital signal converted by the AD conversion unit, and
an offset unit arranged between the light-receiving unit and the AD conversion unit, the offset unit offsetting a direct-current voltage level of the analog signal output from the light-receiving unit by an offset level, and outputting the analog signal to the AD conversion unit,
wherein the offset unit adjusts the offset level so as to cause an average of the analog signal input to the AD conversion unit during a modulation period, in which intensity-modulation is performed using the modulated signal streams, to approach a median of an input voltage range of the AD conversion unit.

2. The position detecting device according to claim 1, wherein the offset unit is configured to set the offset level to a value that causes the average and the median of the input voltage range of the AD conversion unit to agree with each other.

3. The position detecting device according to claim 1, wherein the average is an average of a maximum value and a minimum value of the analog signal.

4. The position detecting device according to claim 3, wherein
the maximum value is a signal value of the analog signal when the light-emitting units are lit simultaneously, and
the minimum value is a signal value of the analog signal when the light-emitting units are turned off simultaneously.

5. The position detecting device according to claim 1, wherein the offset unit adjusts the offset level so as to cause a signal value of the analog signal or an average of the signal value in a state in which only part of the light-emitting units are lit, to approach the median of the input voltage range of the AD conversion unit.

6. The position detecting device according to claim 5, wherein the offset unit sets the offset level to a value that causes the signal value of the analog signal or the average of the signal value in a state in which only part of the light-emitting units are lit, to agree with the median of the input voltage range of the AD conversion unit.

7. The position detecting device according to claim 1, wherein the offset unit sets the offset level in a period in which the modulated signal streams are not set.

8. The position detecting device according to claim 1, wherein
the position detecting device further comprises a variable gain amplifying unit that variably sets a gain, the variable gain amplifying unit being provided between the light-receiving unit and the AD conversion unit, and
the position detecting device is configured to control the gain of the variable gain amplifying unit such that an amplitude of the digital signal converted by the AD conversion unit has a value within a predetermined specific range.

9. The position detecting device according to claim 8, wherein the amplitude of the digital signal is a difference value between a signal value of the digital signal in a state in which the light-emitting units are lit simultaneously during the modulation period, in which the intensity-modulation is performed using the modulated signal streams, and a signal value of the digital signal in a state in which the light-emitting units are turned off simultaneously.

10. The position detecting device according to claim 8, wherein the variable gain amplifying unit changes the gain in a period in which the modulated signal streams are not provided.
